(19) United States
(12) Patent Application Publication
(10) Pub. No.: US 2026/0215127 A1
(43) Pub. Date: Jul. 23, 2026

(54) Display Device

(71) Applicant: LG Display Co., Ltd., Seoul (KR)

(72) Inventors: Yein Hong, Goyang-si (KR); Junyoung Kwon, Goyang-si (KR)

(21) Appl. No.: 19/404,710

(22) Filed: Dec. 1, 2025

(30) Foreign Application Priority Data
Jan. 22, 2025 (KR) 10-2025-0009690

(51) Int. Cl. H10K 59/80; H10K 59/131; H10K 102/00

(52) U.S. Cl. CPC H10K 59/80515; H10K 59/131; H10K 59/873; H10K 2102/311

(57) ABSTRACT

A display device includes: a substrate including a display area and a non-display area surrounding the display area in a plan view of the display device; a bendable area disposed in the non-display area; a lower corner area disposed in the non-display area and connected to the bendable area, wherein the lower corner area has a lower corner end; a plurality of structures disposed on the substrate and in the lower corner area and spaced apart from each other in the plan view; and an anode electrode disposed on the substrate and in the non-display area, wherein the anode electrode has at least one broken area disposed between adjacent ones of the plurality of structures in the plan view.

### CROSS REFERENCE TO RELATED APPLICATION

The present application claims priority to Republic of Korea Patent Application No. 10-2025-0009690, filed on January 22, 2025, the entire contents of which is incorporated herein for all purposes by this reference.

### BACKGROUND OF THE DISCLOSURE

### Field

The present disclosure relates to a display device.

### Description of Related Art

A display device is applied to various electronic devices such as a TV, a smartphone, a laptop computer, and a tablet. To this end, research is being conducted to develop a thin, light weight, and low power consuming display device

Examples of the display device include a LCD (Liquid Crystal Display) device, a FED (Field Emission Display) device, and an OLED (Organic Light-emitting Display) device.

A bezel area of the display device may include an area surrounding an outer side of a display area of the display panel. The bezel area may protect edges of the display panel and internal electronic components from external impact, pressure, or external damage. The bezel area may be visually recognized by a user and thus may be a factor that degrades a sense of immersion in an image emitted from the display area.

Accordingly, recently, there is an increasing demand for a display device implementing a narrow bezel in which a bezel area in which a screen of the display device is not displayed is reduced or a zero bezel that substantially has an effect of not having a bezel area.

### SUMMARY

As a flexible substrate made of a flexible material is applied to the display device, the display panel may include a bendable area that is bent to hide a pad area under the display area. The bendable area may extend from a link area on a lower side in a plan view of the display area of the display panel.

In this case, the bezel area may include upper, left, and right sides in a plan view of the display panel and the lower corner side of the display panel. The bendable area extends from the link area on the lower side of the display area of the display panel. In the bezel area, protective layers having a multilayer structure may be disposed to protect the edge of the display panel and the internal constituent circuits from external impact, pressure, or external damage. The protective layers may include an inorganic insulating material or an organic insulating material.

However, when the organic insulating material is damaged by an external impact or a seam generated during a process, moisture may penetrate through the organic insulating material. The infiltrated moisture may flow to the display area through a moisture permeation path, thereby increasing a defect rate of the display device.

Accordingly, through various experiments, the inventors of the present disclosure have invented a display device capable of preventing external moisture from flowing from the non-display area to the display area.

A technical purpose of the present disclosure is to provide a display device capable of preventing a moisture penetration path from a non-display area to a display area from being generated.

A technical purpose of the present disclosure is to provide a display device capable of increasing a time taken for moisture to permeate into a display area by increasing a length of a moisture penetration path from a non-display area to the display area.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device in accordance with one embodiment of the present disclosure includes: a substrate including a display area and a non-display area surrounding the display area in a plan view of the display device; a bendable area disposed in the non-display area; a lower corner area disposed in the non-display area and connected to the bendable area, wherein the lower corner area has a lower corner end; a plurality of structures disposed on the substrate and in the lower corner area and spaced apart from each other in the plan view; and an anode electrode disposed on the substrate and in the non-display area, wherein the anode electrode has at least one broken area disposed between adjacent ones of the plurality of structures in the plan view.

According to an embodiment of the present disclosure, the display device may include a plurality of structures which are disposed on the lower corner area adjacent to a bendable area of a non-display area of the substrate and which are spaced apart from each other in the plan view. In this regard, the anode electrode disposed under the plurality of structures may be prevented from acting as a path through which external moisture penetrates.

The anode electrode has the broken area defined in an outer area of the lower corner area adjacent to the bendable area of the substrate, thereby preventing external moisture from penetrating through the anode electrode.

According to an embodiment of the present disclosure, the broken area may be disposed between adjacent one of the plurality of structures in the lower corner area of the display panel to increase a length of an external moisture penetration path, thereby delaying a time for external moisture to penetrate into the display area.

Accordingly, the external moisture may be prevented from penetrating into the display area through the anode electrode or the penetration time of the moisture into the display area may be delayed. Accordingly, the signal or voltage for operating the display area DA may be stably provided, such that product reliability may be improved.

According to the embodiments of the present disclosure, since the defect rate of the display device is lowered, the production energy required for additional production of the display device may be reduced, so that there is an effect that greenhouse gas emission may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

FIG. 1 is a plan view of a display panel according to an embodiment of the present disclosure.

FIG. 2 is a cross-sectional view taken along a line I-I' of FIG. 1 according to an embodiment of the present disclosure.

FIGS. 3 and 4 are diagrams according to an embodiment of the present disclosure..

FIGS. 5 and 6 are diagrams according to an embodiment of the present disclosure.

FIGS. 7 and 8 are diagrams according to another embodiment of the present disclosure.

### DETAILED DESCRIPTION OF EMBODIMENTS

Advantages and Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items. Expression such as "at least one of" when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present "on" a second element or layer, the first element may be disposed directly on the second element or may be disposed indirectly on the second element with a third element or layer being disposed between the first and second elements or layers. It will be understood that when an element or layer is referred to as being "connected to", or "coupled to" another element or layer, it may be directly connected to, or coupled to the other element or layer, or one or more intervening elements or layers may be present therebetween. In addition, it will also be understood that when an element or layer is referred to as being "between" two elements or layers, it may be the only element or layer between the two elements or layers, or one or more intervening elements or layers may also be present.

Further, as used herein, when a layer, film, area, plate, or the like is disposed "on" or "on top" of another layer, film, area, plate, or the like, the former may directly contact the latter or still another layer, film, area, plate, or the like may be disposed between the former and the latter. As used herein, when a layer, film, area, plate, or the like is directly disposed "on" or "on top" of another layer, film, area, plate, or the like, the former directly contacts the latter and still another layer, film, area, plate, or the like is not disposed between the former and the latter. Further, as used herein, when a layer, film, area, plate, or the like is disposed "beneath" or “under” another layer, film, area, plate, or the like, the former may directly contact the latter or still another layer, film, area, plate, or the like may be disposed between the former and the latter. As used herein, when a layer, film, area, plate, or the like is directly disposed "beneath" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms "first", "second", "third", and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term 'or' means 'inclusive or' rather than 'exclusive or'. That is, unless otherwise stated or clear from the context, the expression that 'x uses a or b' means one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase 'immediately transferred' or 'directly transferred' is used.

Throughout the present disclosure, "A and/or B" means A, B, or A and B, unless otherwise specified, and "C to D" means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to an embodiment of the present disclosure will be described with reference to the drawings.

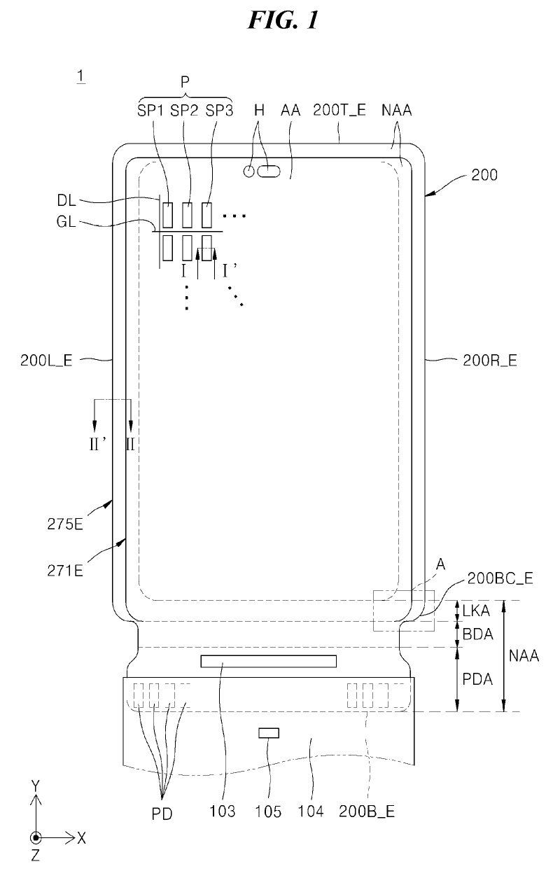

FIG. 1 is a plan view of a display panel according to an embodiment of the present disclosure.

Referring to FIG. 1, a display device 1 according to an embodiment of the present disclosure may include a display panel 200, a printed circuit board 104, a control circuit chip 105, etc.

The display panel 200 may include a display area AA and a non-display area NAA. The display area AA is an area in which an image is displayed, and a plurality of pixels P, data lines DL, and gate lines GL may be disposed in the display area. The non-display area NAA may be an area in which no image is displayed. The non-display area NAA may be located in an peripheral area (or an edge area) of the display panel 200. However, the present disclosure is not limited thereto. For example, an area other than a light emission area in which light is emitted to the outside in the display area AA may be referred to as the non-display area NAA. The bezel area of the display device may be defined by the non-display area NAA. The bezel area BZA may surround an outside of the display area AA.

The non-display area NAA may include four side ends 200T_E, 200L_E, 200R_E, and 200B_E located as the outermost side of the display panel 200. The outermost side ends 200T_E, 200L_E, 200R_E, and 200B_E may include an upper side end 200T_E, a left side end 200L_E, a right side end 200R_E, and a lower side end 200B_E. Further, a lower corner end 200BC_E is disposed between each of the left side end 200L_E and the right side end 200R_E and the lower side end 200B_E. The lower corner end 200BC_E refers each of outermost right and left portions of the link area LKA. The bendable area BDA and the pad area PDA may be disposed between the link area and the lower side end 200B_E of the display panel 200.

Lines for providing an electrical signal to the display area AA or receiving an electrical signal from the display area AA may be disposed in the non-display area NAA. For example, a gate driver for supplying a gate signal to the plurality of sub-pixels SP1, SP2, and SP3 of the display area AA may be disposed in the non-display area NAA. The gate driver may be disposed at each of right and left edges of the non-display area NAA in a gate in panel (GIP) manner. The gate driver may transmit a gate signal through the gate lines GL.

The non-display area NAA may include a pad area PDA in which a driving circuit chip 103 and a plurality of pads PD are disposed. The driving circuit chip 103 may transmit a data signal to the plurality of sub-pixels SP1, SP2, and SP3 through the plurality of data lines DL in the display area AA. For example, the driving circuit chip 103 may be a data driving circuit chip. However, embodiments of the present disclosure are not limited thereto.

The gate lines GL may extend in the first direction X of the display panel 200, and the data lines DL may intersect the gate lines GL and extend in the second direction Y of the display panel 200.

The non-display area NAA may include the link area LKA. The link area LKA may include data link lines for electrically connecting the plurality of data lines DL of the display area AA to the driving circuit chip 103, or touch link lines for electrically connecting touch lines to the driving circuit chip 103. For example, the link area LKA may be disposed between the display area AA and the pad area PDA, and the bendable area BDA may be disposed between the link area LKA and the pad area PDA.

The bendable area BDA of the display panel 200 may bent to allow a printed circuit board 104 on which a control circuit chip 105 is disposed to face a rear surface of the display area AA of the display panel 200. The control circuit chip 105 may control the driving circuit chip 103 and the gate driver.

As the bendable area BA of the display panel 200 is bent, the pad area PDA of the non-display area NAA may be located under the display area AA. Accordingly, a lower side area of the non-display area NDA1 of the display device 1 recognized by the viewer in front of the display device 1 may be reduced.

The display area AA may include a plurality of pixels P and a hole H. The hole H may be an area in which an electronic component for adding various functions to the display device 1 is disposed. For example, the electronic component may include a camera module for taking a picture or an image, or may include various sensor devices for detecting an external object. The sensor device may include at least one of a proximity sensor, a gesture sensor, a color sensor, a biometric sensor, and an infrared sensor. However, embodiments of the present disclosure are not limited thereto.

One pixel P may include a plurality of sub-pixels SP1, SP2, and SP3. An image may be displayed in the display area AA through the plurality of sub-pixels SP1, SP2, and SP3. The plurality of sub-pixels SP1, SP2, and SP3 may be arranged in an array in the display area AA. In an example, the plurality of sub-pixels SP1, SP2, and SP3 may be arranged in a matrix manner and may be spaced apart from each other in the first direction of the display area AA and the second direction intersecting the first direction. The first direction may be a horizontal direction, an X-axis direction, or a row direction, and the second direction may be a vertical direction, a Y-axis direction, or a column direction. However, the present disclosure is not limited thereto, and the arrangement shape, arrangement order, and arrangement direction of the sub-pixels SP1, SP2, and SP3 may be variously changed.

In the present disclosure, one pixel P is configured to include the first sub-pixel SP1, the second sub-pixel SP2, and the third sub-pixel SP3. However, the present disclosure is not limited thereto. For example, one pixel P may further include an additional sub-pixel.

The sub-pixels SP1, SP2, and SP3 may be implemented to emit light of the same color such as white light. Alternatively, the sub-pixels SP1, SP2, and SP3 may be implemented to emit light of different colors such as red, green, and blue colors. For example, the first sub-pixel SP1 may emit light of red, the second sub-pixel SP2 may emit light of green, and the third sub-pixel SP3 may emit light of blue.

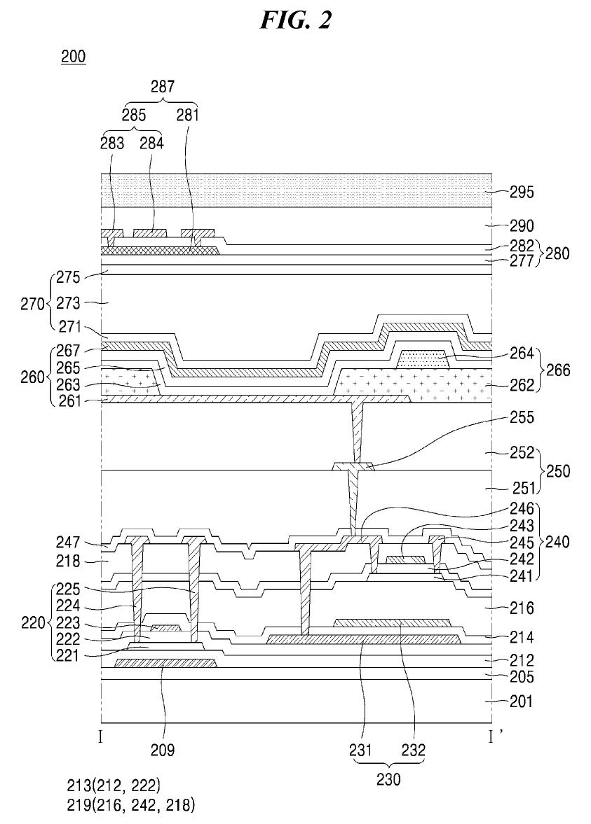

FIG. 2 is a cross-sectional view taken along a line I-I' of FIG. 1 according to an embodiment of the present disclosure. FIG. 2 schematically illustrates one sub-pixel of a display device. In the present disclosure, for convenience of description, an example of a configuration of one sub-pixel is described. However, the present disclosure is not limited thereto.

Referring to FIG. 2, the display panel 200 may include a pixel driving circuit including a plurality of transistors 220 and 240 disposed on a substrate 201, a light-emitting element 260, and a touch sensor 287.

One sub-pixel may include a light-emitting element 260 and a pixel driving circuit that applies a driving current to the light-emitting element 260. The pixel driving circuit is disposed on the substrate 201, and the light-emitting element 260 is disposed on the pixel driving circuit. The pixel driving circuit may include a plurality of transistors 220 and 240 and a storage capacitor 230. In an example, the plurality of transistors 220 and 240 may include a first transistor 220 and a second transistor 240.

The substrate 201 may be a flexible plastic substrate. When the substrate 201 is formed as a plastic film, the substrate 201 may include multiple layers made of an insulating material. A first buffer layer 205 may be disposed on the substrate 201. The first buffer layer 205 may cover a surface of the substrate 201. The first buffer layer 205 may reduce or prevent penetration of moisture, oxygen, or impurities through the substrate 201. The first buffer layer 205 may be embodied as a single layer or a multilayer made of an inorganic insulating material such as silicon oxide (SiOx) or silicon nitride (SiNx). The first buffer layer 205 may entirely cover the surface of the substrate 201 in the display area AA. For example, the first buffer layer 205 may extend to the non-display area NAA surrounding the outside of the display area AA.

A light-shielding layer 209 may be disposed on the first buffer layer 205. The light-shielding layer 209 may prevent external light from being incident on the transistor. To this end, the light-shielding layer 209 may include an opaque metal material. A second buffer layer 212 may be disposed on the light-shielding layer 209. The second buffer layer 212 may protect the transistor from moisture, oxygen, or impurities. The second buffer layer 212 may be embodied as a single layer or a multilayer made of an inorganic insulating material such as silicon oxide (SiOx) or silicon nitride (SiNx). However, embodiments of the present disclosure are not limited thereto. The second buffer layer 212 may entirely cover the surface of the substrate 201 in the display area AA. For example, the second buffer layer 212 may extend to the non-display area NAA surrounding the outside of the display area AA.

The first transistor 220 may be disposed on the second buffer layer 212. The first transistor 220 may include a first semiconductor layer 221, a first gate insulating layer 222, a first gate electrode 223, a first source electrode 224, and a first drain electrode 225. In an example, the first transistor 220 may be a switching transistor.

The first semiconductor layer 221 may include a channel area and source/drain areas. An area of the first semiconductor layer 221 overlapping the first gate electrode 223 in the vertical direction may be a channel area. The source/drain areas may be disposed on both opposing sides of the channel area, respectively. The first semiconductor layer 221 may include one of a polysilicon semiconductor layer and a low-temperature polysilicon semiconductor layer, or a combination thereof. In another example, the first semiconductor layer 221 may include an oxide semiconductor layer. For example, the first semiconductor layer 221 may include at least one of an oxide semiconductor material such as IGZO (Indium Gallium Zinc Oxide) or IZO (Indium Zinc Oxide).

When the first semiconductor layer 221 includes the oxide semiconductor layer, the first transistor 220 may be embodied as an oxide thin-film transistor. The first semiconductor layer 221 may be disposed to overlap the light-shielding layer 209 in the vertical direction. The light-shielding layer 209 may prevent external light from being incident on the first semiconductor layer 221.

The first gate insulating layer 222 may be disposed between the first semiconductor layer 221 and the first gate electrode 223. The first gate insulating layer 222 may extend outwardly while covering the first semiconductor layer 221. The first gate insulating layer 222 may be embodied as a single layer or a stack of a plurality of layers made of an inorganic insulating material such as silicon oxide (SiOx) or silicon nitride (SiNx). The first gate insulating layer 222 may entirely cover the surface of the substrate 201 in the display area AA. For example, the first gate insulating layer 222 may extend to the non-display area NAA surrounding the outside of the display area AA. In the non-display area NAA, the second buffer layer 212 and the first gate insulating layer 222 may be arranged in the vertical direction so as to be in contact with each other to constitute a first insulating structure 213.

The first gate electrode 223 may be disposed on the first gate insulating layer 222. A first interlayer insulating layer 214 may be disposed on the first gate electrode 223. The first interlayer insulating layer 214 may be embodied as a single layer or a stack of multiple layers made of an inorganic insulating material such as silicon oxide (SiOx) or silicon nitride (SiNx). In an example, the first interlayer insulating layer 214 may extend to the non-display area NAA surrounding the outside of the display area AA.

The first source electrode 224 and the first drain electrode 225 may be electrically connected to the first semiconductor layer 221.

The storage capacitor 230 may include a first storage electrode 231 and a second storage electrode 232. For example, the first storage electrode 231 and the first gate electrode 223 may be formed on the same layer 222. For example, the first storage electrode 231 may be disposed on the first gate insulating layer 222 and at a position horizontally spaced apart from the first gate electrode 223. The first storage electrode 231 may be made of the same material as that of the first gate electrode 223. The second storage electrode 232 may be disposed on the first interlayer insulating layer 214 so as to overlap the first storage electrode 231 in the vertical direction.

Each of the first storage electrode 231 and the second storage electrode 232 may be embodied as a single layer or as a stack of multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

A second interlayer insulating layer 216 may be disposed on the second storage electrode 232. The second interlayer insulating layer 216 may be embodied as a single layer or a stack of multiple layers made of an inorganic insulating material such as silicon oxide (SiOx) or silicon nitride (SiNx). In an example, the second interlayer insulating layer 216 may extend to the non-display area NAA surrounding the outside of the display area AA.

The second transistor 240 may be disposed on the second interlayer insulating layer 216 so as to be spaced apart from the first transistor 220. The second transistor 240 may be electrically connected to the first transistor 220. For example, the second transistor 240 may include a second semiconductor layer 241, a second gate insulating layer 242, a second gate electrode 243, a second source electrode 245, and a second drain electrode 246. In an example, the second transistor 240 may be a driving transistor electrically connected to the light-emitting element 260.

The second semiconductor layer 241 may include a channel area and source/drain areas. A area of the second semiconductor layer 241 overlapping the second gate electrode 243 in the vertical direction may be a channel area. The source/drain areas may be disposed on both opposing sides of the channel area, respectively. The second semiconductor layer 241 may include an oxide semiconductor layer. For example, the second semiconductor layer 241 may include at least one of an oxide semiconductor material such as indium gallium zinc oxide (IGZO) or indium zinc oxide (IZO). In an example, the second semiconductor layer 241 may be disposed to overlap the storage capacitor 230 in the vertical direction. Accordingly, the storage capacitor 230 may prevent the external light from the outside out of the substrate 201 from being incident on the second semiconductor layer 241. Accordingly, this may prevent the characteristics of the second transistor 240 from being changed by the external light.

The second gate insulating layer 242 may be disposed between the second semiconductor layer 241 and the second gate electrode 243. The second gate insulating layer 242 may extend outwardly while covering the second semiconductor layer 241. For example, the second gate insulating layer 242 may extend to the non-display area NAA surrounding the outside of the display area AA. The second gate insulating layer 242 may be embodied as a single layer or a stack of a plurality of layers made of an inorganic insulating material such as silicon oxide (SiOx) or silicon nitride (SiNx).

Each of the first gate electrode 223 or the second gate electrode 243 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, an example of the material is not limited thereto.

A third interlayer insulating layer 218 may be disposed on the second gate electrode 243. The third interlayer insulating layer 218 may include an insulating material. For example, the third interlayer insulating layer 218 may include an inorganic insulating material such as silicon oxide (Six), silicon nitride (SiNx), or silicon oxynitride (SiON), and may be embodied as a single layer or a stack of multiple layers. In an example, the third interlayer insulating layer 218 may extend to the non-display area NAA surrounding the outside of the display area AA. In the non-display area NAA, the second interlayer insulating layer 216, the second gate insulating layer 242, and the third interlayer insulating layer 218 may be arranged in the vertical direction so as to be in contact with each other to constitute a second insulating structure 219.

The first source electrode 224, the first drain electrode 225, the second source electrode 245, and the second drain electrode 246 may be disposed on the third interlayer insulating layer 218.

The first source electrode 224 and the first drain electrode 225 may extend through the third interlayer insulating layer 218, the second gate insulating layer 242, the second interlayer insulating layer 216, the first interlayer insulating layer 214, and the first gate insulating layer 222 so as to be in direct contact with and be electrically connected to the source/drain areas of the first semiconductor layer 221, respectively.

The second source electrode 245 and the second drain electrode 246 may extend through the third interlayer insulating layer 218 and the second gate insulating layer 242 so as to directly contact and be electrically connected to the source/drain areas of the second semiconductor layer 241, respectively. The second drain electrode 246 of the second transistor 240 may be electrically connected to the storage capacitor 230. For example, a portion of the second drain electrode 246 may extend through the third interlayer insulating layer 218, the second gate insulating layer 242, the second interlayer insulating layer 216, and the first interlayer insulating layer 214 so as to be in direct contact with and be electrically connected to the first storage electrode 231 of the storage capacitor 230.

Each of the first source electrode 224, the first drain electrode 225, the second source electrode 245, or the second drain electrode 246 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, each of the first source electrode 224, the first drain electrode 225, the second source electrode 245, or the second drain electrode 246 may have a stack structure of titanium layer/aluminum layer/titanium layer (Ti/Al/Ti).

A passivation layer 247 may be disposed on the first source electrode 224, the first drain electrode 225, the second source electrode 245, or the second drain electrode 246. The passivation layer 247 may include an inorganic insulating material such as silicon oxide, silicon nitride, and silicon oxynitride, and may be embodied as a single layer or a stack of multiple layers. The passivation layer 247 may protect the pixel driving circuit disposed thereunder.

A planarization layer 250 may be disposed on the passivation layer 247. The planarization layer 250 may planarize a step caused due to the pixel driving circuit thereunder. The planarization layer 250 may include a multilayer structure of a first planarization layer 251 and a second planarization layer 252. For example, the planarization layer 250 may include an organic insulating material such as polyimide or acrylic resin. In an example, each of the first planarization layer 251 and the second planarization layer 252 may extend to the non-display area NAA surrounding the outside of the display area AA.

A pixel contact electrode 255 may be disposed on the first planarization layer 251. The pixel contact electrode 255 may extend thorough the first planarization layer 251 and the passivation layer 247 so as to directly contact the second drain electrode 246 of the second transistor 240.

The light-emitting element 260 may be formed on the planarization layer 250. For example, the light-emitting element 260 may be disposed on the second planarization layer 252. The light-emitting element 260 may include an anode electrode 261, a light-emitting layer 263, a cathode electrode 265, and a capping layer 267.

The light-emitting element 260 may be electrically connected to the pixel driving circuit via the anode electrode 261. For example, the anode electrode 261 may extend through the second planarization layer 252 so as to directly contact the pixel contact electrode 255. Accordingly, the anode electrode 261 may be electrically connected to the second transistor 240 via the pixel contact electrode 255. However, FIG. 2 illustrates an example of a scheme of supplying a current to the anode electrode 261, and the present disclosure is not limited to physical contact between the second transistor 240 as the driving transistor and the anode electrode 261. In an example, the switching transistor ST electrically connected to the anode electrode 261 may be a light-emission transistor. For example, the light-emission transistor may control the turn-on and turn-off states of the light-emitting element 260. The pixel contact electrode 255 may include a conductive material. For example, the pixel contact electrode 255 may include a metal material such as aluminum (Al), chromium (Cr), copper (Cu), titanium (Ti), molybdenum (Mo), and tungsten (W). In an example, the pixel contact electrode 255 may have a multilayer structure of titanium layer/aluminum layer/titanium layer (Ti/Al/Ti).

The anode electrode 261 may include a transparent conductive layer. For example, the anode electrode 261 may include ITO (Indium Tin Oxide) or IZO (Indium Zinc Oxide). Alternatively, the anode electrode 261 may have a single-layer or a multi-layer structure including a reflective metal film made of one of silver (Ag), aluminum (Al), gold (Au), nickel (Ni), and chromium (Cr) or an alloy thereof. The anode electrode 261 may also be referred to as a pixel electrode.

A bank 262 may be disposed on the anode electrode 261. The bank 262 may be disposed to cover an edge of the anode electrode 261. A portion of the bank 262 may extend to the second planarization layer 252. A portion of an upper surface of the anode electrode 261 not covered with the bank 262 so as to be exposed may be the light emission area EA. The bank 262 may be made of an organic insulating material. The bank 262 may include, for example, photosensitive polyimide, photoacryl, or benzocyclobutene (BCB).

A spacer 264 may be further disposed on the bank 262. The spacer 264 may be disposed to prevent damage to the bank 262 and the anode electrode 261 during the process. The spacer 264 may be made of the same material as that of the bank 262. The bank 262 and the spacer 264 may be stacked vertically to constitute an organic insulating structure 266.

The light-emitting layer 263 may be disposed on the anode electrode 261. The light-emitting layer 263 may include a hole transport layer HTL, an organic light-emitting layer EML, an electron transport layer ETL, a hole blocking layer HBL, a hole injecting layer HIL, an electron blocking layer EBL, and an electron injecting layer EIL. The light light-emitting layer 263 may have a multi-stack structure in which two or more organic emission layers EML are stacked.

The cathode electrode 265 may be disposed on the light-emitting layer 263. The cathode electrode 265 may be commonly connected to the light-emitting layer 263 formed in all pixels. Therefore, the cathode electrode 265 may also be referred to as a common electrode. The cathode electrode 265 may include a transflective conductive material. For example, the cathode electrode may be made of a metal material such as magnesium (Mg), silver (Ag), or an alloy (Ag-Mg) of silver (Ag) and magnesium (Mg). In an example, the cathode electrode 265 may include a transparent conductive layer such as indium-tin-oxide (ITO) or indium-zinc-oxide (IZO).

The capping layer 267 may be disposed on the cathode electrode 265. The capping layer 267 may prevent light generated from the light-emitting layer 263 from being lost, thereby improving light extraction efficiency.

The encapsulation stack 270 may be disposed on the light-emitting element 260. The encapsulation stack 270 may protect the light-emitting element 260 from external oxygen or moisture. The encapsulation stack 270 may extend to the non-display area NAA outside the display area AA while covering the display area AA.

The encapsulation stack 270 may include a multilayer structure in which a first encapsulation layer 271, a second encapsulation layer 273, and a third encapsulation layer 275 are stacked. The second encapsulation layer 273 may be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271 and may have a sufficient thickness so as to have a flat upper surface. The second encapsulation layer 273 may prevent foreign substances from penetrating into the light-emitting element 260. The third encapsulation layer 275 may be disposed on the second encapsulation layer 273. Each of the first encapsulation layer 271 and the third encapsulation layer 275 may extend to the non-display area NAA surrounding the outside of the display area AA.

Each of the first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one of silicon nitride (SiNx), silicon oxide (SiOx), or silicon oxynitride (SiON). The second encapsulation layer 273 may include at least one of epoxy, polyimide, polyethylene, and acrylate.

A touch area may be disposed on the encapsulation stack 270. The touch area may include a touch buffer layer 277, a touch sensor 287, a touch interlayer insulating layer 282, a first touch protection layer 290, and a second touch protection layer 295.

The touch buffer layer 277 may be disposed on the third encapsulation layer 275. The touch buffer layer 277 may reduce stress between the encapsulation stack 270 and the layer of the touch sensor 287 to prevent the encapsulation stack 270 and the light-emitting element 260 from being damaged. The touch buffer layer 277 may include an inorganic insulating material. For example, the touch buffer layer 277 may include silicon nitride (SiNx).

The touch sensor 287 may include a plurality of touch electrodes 285 and a bridge electrode 281. The plurality of touch electrodes 285 and the bridge electrode 281 may be disposed in different layers. For example, the bridge electrode 281 may be disposed on the touch buffer layer 277. The plurality of touch electrodes 285 may be disposed on the touch interlayer insulating layer 282. The plurality of touch electrodes 285 may include a first touch electrode 283 and a second touch electrode 284. The bridge electrode 281 may electrically connect adjacent first touch electrodes 283 to each other. To this end, the first touch electrode 283 may extend through the touch interlayer insulating layer 282 so as to be connected to the bridge electrode 281. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or a stack of multiple layers made of one of molybdenum (Mo), aluminum (Al), chromium (Cr), gold (Au), titanium (Ti), nickel (Ni), neodymium (Nd), and copper (Cu) or an alloy thereof.

Each of the touch buffer layer 277 and the touch interlayer insulating layer 282 may extend toward the non-display area NAA.

The first touch protection layer 290 may be disposed on the touch sensor 287. The first touch protection layer 290 may prevent damage to the touch sensor 287 from external impact and moisture. The first touch protection layer 290 may include an organic insulating material. For example, the first touch protection layer 290 may be made of a photosensitive acrylic-based or polyimide-based organic material. The first touch protection layer 290 may extend to the non-display area NAA. For example, the first touch protection layer 290 may extend to the non-display area NAA surrounding the outside of the display area AA.

The second touch protection layer 295 may be disposed on the first touch protection layer 290. The second touch protection layer 295 may further protect the touch sensor 287 from external impact and moisture. In addition, the second touch protection layer 295 may planarize a step caused by patterns constituting the touch sensor 287 disposed thereunder. The second touch protection layer 295 may include an organic insulating material. For example, the second touch protection layer 295 may include the same organic insulating material as that of the first touch protection layer 290. However, embodiments of the present disclosure are not limited thereto. For example, the second touch protection layer 295 may include an organic insulating material different from that of the first touch protection layer 290.

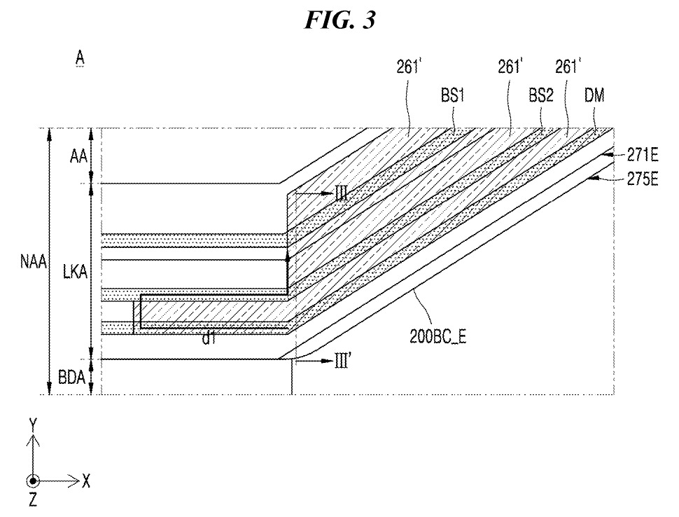

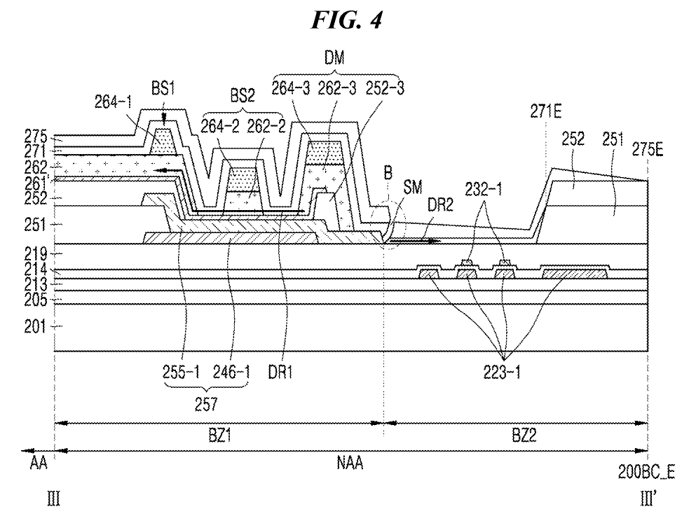

FIGS. 3 and 4 are diagrams according to an embodiment of the present disclosure. FIG. 3 is an enlarged plan view of an area A of FIG. 1 according to an embodiment of the present disclosure. FIG. 4 is a cross-sectional view taken along a line III-III' of FIG. 3 according to an embodiment of the present disclosure. In FIGS. 3 and 4, the same constituent elements may employ the same reference numerals.

FIG. 3 is an enlarged view of a corner area including the lower corner end 200BC_E of the display panel 200 (see FIG. 1). FIG. 3 illustrates an example of a right corner area including a right lower corner end among a left lower corner end and the right lower corner end of the display panel 200 (see FIG. 1) for convenience of illustration. However, embodiments of the present disclosure are not limited thereto. For example, the left corner area including the left lower corner end may also be configured in the same manner as the right corner including the right lower corner end. Accordingly, hereinafter, the right lower corner end may be referred to as the lower corner end 200BC_E.

Referring to FIGS. 1, 3, and 4, the display panel 200 may include corresponding to a lower corner portion, which is connected to the bendable area BDA through the link area LKA and is disposed on a lower side in the plan view of the display area AA. The non-display area NAA surrounds the outside of the display area AA. The non-display area NAA may include a first zone BZ1 and a second zone BZ2. The first zone BZ1 may be located closer to the display area AA than the second zone BZ2 may be. The second zone BZ2 may be disposed outwardly of the first zone BZ1. The first zone BZ1 surround the display area AA. For example, the second zone BZ2 may be an area surrounding the first zone BZ1. The second zone BZ2 may include the lower corner end 200BC_E.

The first zone BZ1 of the non-display area NAA may be an area in which a signal line 257 and a plurality of structures BS1, BS2, and DM are disposed. The signal line 257 may extend from the display area AA and be disposed in the non-display area NAA including the link area LKA. For example, the first zone BZ1 may be an area in which one end of the signal line 257 is disposed. However, embodiments of the present disclosure are not limited thereto.

The plurality of structures BS1, BS2 and DM may include a first barrier structure BS1, a second barrier structure BS2, and a dam DM. The first barrier structure BS1 among the plurality of structures BS1, BS2, and DM may be disposed closest to the display area AA. The dam DM may be disposed at a position farthest from the display area AA. The second barrier structure BS2 may be disposed between the first barrier structure BS1 and the dam DM. The first barrier structure BS1, the second barrier structure BS2, and the dam DM may be disposed in the non-display area NAA surrounding the outside of the display area AA. For example, each of the first barrier structure BS1, the second barrier structure BS2, and the dam DM may extend in a line shape along at least the upper side, the left side, and the right side of the display panel 200.

Insulating material layers 205, 213, 214, and 219 extending from the display area AA may be vertically stacked on the substrate 201 of a portion of the non-display area NAA corresponding to the lower corner area. Accordingly, the insulating material layers 205, 213, 214, and 219 may constitute a stack of multiple layers. For example, the insulating material layers 205, 213, 214, and 219 may include a structure in which the first buffer layer 205, the first insulating structure 213, the first interlayer insulating layer 214, and the second insulating structure 219 are sequentially stacked on the substrate.

First conductive patterns 223-1 may be disposed on the first insulating structure 213 so as to be spaced apart from each other. The first conductive patterns 223-1 may be made of the same material as that of the first gate electrode 223 and may be formed in the same process as the process for forming the first gate electrode 223. The first conductive patterns 223-1 may be covered with the first interlayer insulating layer 214. Second conductive patterns 232-1 may be disposed on the first interlayer insulating layer 214 so as to be spaced apart from each other. The second conductive patterns 232-1 may be made of the same material as that of the second storage electrode 232 and may be formed in the same process as the process for forming the second storage electrode 232. However, embodiments of the present disclosure are not limited thereto. The second insulating structure 219 may be disposed on the second conductive patterns 232-1. The first conductive patterns 223-1 and the second conductive patterns 232-1 may be disposed to overlap each other vertically.

For example, the first conductive patterns 223-1 or the second conductive patterns 232-1 may be conductive lines that transmit signals or voltages to the pixel driving circuit disposed in the display area AA. However, embodiments of the present disclosure are not limited thereto. For example, the first conductive patterns 223-1 or the second conductive patterns 232-1 may extend toward the bendable area BDA.

The signal line 257 may be disposed on the second insulating structure 219. The signal line 257 may include a first line 246-1 and a second line 255-1 disposed on the first line 246-1. The second line 255-1 may be in contact with and electrically connected to the first line 246-1.

The first line 246-1 may include the same material as that of the second source electrode 245 or the second drain electrode 246 and may be formed in the same process as the process for forming the second source electrode 245 or the second drain electrode 246. The second line 255-1 disposed on the first line 246-1 may include the same material as that of the pixel contact electrode 255 and may be formed in the same process as the process for forming the pixel contact electrode 255. For example, the signal line 257 may include a low potential power (VSS) line. The low-potential power (VSS) line may supply a reference voltage to the light-emitting element 260 disposed in the display area AA. The low-potential power (VSS_ line may be disposed to surround the upper side, the left side, and the right side of the display area AA in order to lower the resistance thereof.

One end of the first line 246-1 of the signal line 257 may be covered with the first planarization layer 251 extending from the display area AA. One end of the second line 255-1 may be disposed on the first planarization layer 251. The second line 255-1 may extend from first planarization layer 251 onto the first line 246-1 and may extend onto a portion of an upper surface of the second insulating structure 219.

One end of the second line 255-1 of the signal line 257 may be covered with the second planarization layer 252 extending from the display area AA.

The bank 262 may be disposed on the second planarization layer 252.

The first barrier structure BS1 disposed in the first zone BZ1 may be disposed on the bank 262. The first barrier structure BS1 may include a first layer 264-1 including an organic insulating material. The first layer 264-1 of the first barrier structure BS1 may be formed in the same process as the process of forming the spacer 264 of the display area AA. Accordingly, the first layer 264-1 of the first barrier structure BS1 may be made of the same material as that of the spacer 264.

The second barrier structure BS2 may be spaced apart from the first barrier structure BS1 and may be disposed in the first zone BZ1. The second barrier structure BS2 may have a structure in which a first layer 262-2 and a second layer 264-2 are vertically stacked on the anode electrode 261. For example, the first layer 262-2 of the second barrier structure BS2 may be made of the same material as that of the bank 262 and may be formed in the same process as the process for forming the bank 262. The second layer 264-2 of the second barrier structure BS2 may be made of the same material as that of the spacer 264 and may be formed in the same process as the process for forming the spacer 264.

The dam DM may be spaced apart from the second barrier structure BS2 and may be disposed in the first zone BZ1. The dam DM may have a structure in which a first layer 252-3, a second layer 262-3, and a third layer 264-3 are sequentially stacked such that that the first layer 252-3 is the lowest layer. For example, the first layer 252-3 of the dam DM may be made of the same material as that of the second planarization layer 252 and may be formed in the same process as the process for forming the second planarization layer 252. The second layer 262-3 on the first layer 252-3 may be made of the same material as that of the bank 262 and may be formed in the same process as the process for forming the bank 262. The third layer 264-3 on the second layer 262-3 may be made of the same material as that of the spacer 264 and may be formed in the same process as the process for forming the spacer 264.

An anode electrode part 261′ may be disposed between the second planarization layer 252 and the bank 262. The anode electrode part 261′ may be made of the same material as that of the anode electrode 261 of the light-emitting element 260 in the display area AA and may be formed in the same process as the process for forming the anode electrode 261. The anode electrode part 261′ may be disposed in the display area AA and the non-display area NAA. The signal line 257 and the cathode electrode 254 (see FIG. 2) may extend from the display area AA to the non-display area NAA surrounding the outside of the display area AA. Accordingly, the anode electrode part 261′ may be electrically connected to the signal line 257 and the cathode electrode 265 in the non-display area NAA surrounding the outside of the display area AA. For example, the signal line 257, the anode electrode part 261′, and the cathode electrode 265 may be electrically connected to each other in the non-display area NAA at the upper, left, and right sides of the display panel 200. The anode electrode part 261′ may be cut away so as to be broken in a portion of the non-display area NAA close to the lower corner end 200BC_E of the display panel (i.e. in the lower corner area).

In the portion of the non-display area NAA close to the lower corner end 200BC_E of the display panel, an end of the broken anode electrode part 261′ may be covered with an organic insulating material. For example, the end of the broken anode electrode part 261′ may be covered with the second layer 262-3 of the dam DM. For example, referring to FIG. 3, an end of the anode electrode part 261′ in the second direction Y as the column direction of the display panel may be covered with the dam DM, whereas an end of the anode electrode part 261′ in the first direction X as the row direction of the display panel may be exposed through a space between the second barrier structure BS2 and the dam DM. For another example, another end of the anode electrode part 261′ in the first direction X may be exposed through a space between the second barrier structure BS2 and the first barrier structure BS1.

The exposed end of the anode electrode part 261′ may form an air gap and act as a path through which moisture may flow. When a damage point occurs in the dam DM or a portion adjacent to the dam DM in the lower corner area, moisture may be introduced through the damage point and may flow along the path indicated by an arrow d1 in FIG. 3 such that the moisture may invade into the pixels P of the display area AA.

For example, the moisture introduced through the damage point of the dam DM may flow in the first direction X as the row direction along the shape of the dam DM including the organic insulating material, and may flow to the second barrier structure BS2 through the air gap extending in the column direction of the anode electrode part 261′ disposed between the dam DM and the second barrier structure BS2. The moisture having flowed toward the second barrier structure BS2 may flow in the first direction X as the row direction along the shape of the second barrier structure BS2, and may flow to the first barrier structure BS1 through the air gap extending in the column direction of the anode electrode part 261′ disposed between the second barrier structure BS2 and the first barrier structure BS1. Then, the moisture may be introduced into the display area AA through the first barrier structure BS1 disposed adjacent to the display area AA.

For example, referring to FIGS. 1 and 4, in the non-display area NAA at the upper side, the left side, and the right side of the display panel 200, an side 271E of the first encapsulation layer 271 may be located inwardly of an side 275E of the third encapsulation layer 275, and thus the first encapsulation layer 271 may be covered with a sufficient thickness of the third encapsulation layer 275. In addition, the second line 255-1 of the signal line 257 may be entirely covered with the second planarization layer 252 and thus may not be exposed.

However, the non-display area NAA may become narrower as the non-display area NAA extends toward the lower corner end 200BC_E from which the bendable area BDA of the display panel 200 extends. Accordingly, a point where the first encapsulation layer 271 and the third encapsulation layer 275 meet each other may occur in the lower corner end 200BC_E. In the second zone BZ2 including a point where the first encapsulation layer 271 and the third encapsulation layer 275 meet each other, the end of the signal line 257 may be not covered with the second planarization layer 252 so as to be exposed. For example, the first planarization layer 251 and the second planarization layer 252 may be disposed in an area including the lower corner end 200BC_E in the second zone BZ2. Accordingly, the end of the signal line 257 may be covered only with the first encapsulation layer 271 and the third encapsulation layer 275. Each of the first encapsulation layer 271 and the third encapsulation layer 275 may be referred to as an inorganic insulating structure.

A seam SM may occur at a portion B of the first encapsulation layer 271 and the third encapsulation layer 275 covering the end of the signal line 257. However, a thickness of a portion of the first encapsulation layer 271 covering the end of the second signal line 255-1 may be reduced as the first encapsulation layer 271 extends toward the lower corner end 200BC_E and the side 271E of the first encapsulation layer 271. The portion B covering the end of the signal line 257 may act as a moisture inflow point.

The moisture may penetrate through the end of the signal line 257 into the portion where the seam SM is present. The moisture permeated through the end of the signal line 257 may propagate in both of the first direction DR1 in which the plurality of structures BS1, BS2, and DM extend and the second direction DR2 in which the lower corner end 200BC_E extends. The moisture flowing in the first direction DR1 may flow to the display area AA via the portion of the anode electrode part 261′ disposed under the plurality of structures BS1, BS2, and DM as a moisture permeable path.

The moisture having flowed to the display area DA may corrode the light-emitting element or the line of the pixel driving circuit that applies a driving current to the light-emitting element, or damage the light-emitting layer of the light-emitting element, thereby causing defects such as a dark spot defect in which the pixel does not emit light.

Accordingly, another embodiment of the present disclosure may provide a structure in which the anode electrode part 261′ may be prevented from becoming a moisture penetration path in the non-display area NAA including the lower corner end 200BC_E of the display panel 200.

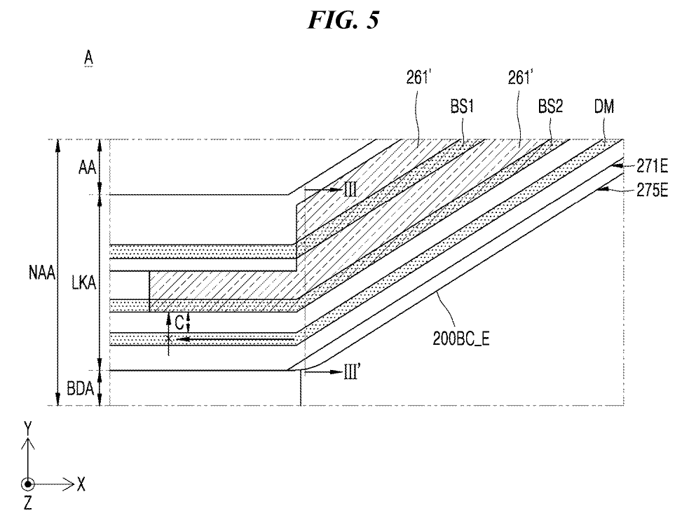

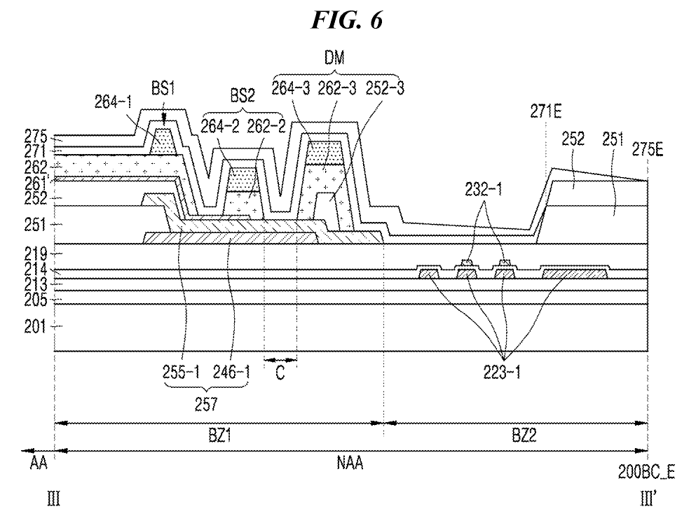

FIGS. 5 and 6 are diagrams according to another embodiment of the present disclosure. FIG. 5 is an enlarged plan view of the area A of FIG. 1. FIG. 6 is a cross-sectional view taken along a line III-III' of FIG. 5. In FIGS. 5 and 6, descriptions of the same components as those of FIGS. 3 and 4 will be briefly or omitted. The same constituent elements may employ the same reference numerals.

Referring to FIGS. 5 and 6, the lower corner area of the non-display area NAA of the display panel 200 may include the first zone BZ1 and the second zone BZ2. The lower corner area of the display panel 200 may be connected to the bendable area BDA.

The first barrier structure BS1, the second barrier structure BS2, and the dam DM may be disposed in the first zone BZ1 of the non-display area NAA. The second zone BZ2 may be located outwardly of the first zone BZ1.

The insulating material layers 205, 213, 214, and 219 extending from the display area AA may be vertically stacked on a portion of the substrate 201 of the non-display area NAA corresponding to the lower corner area. Accordingly, the insulating material layers 205, 213, 214, and 219 may constitute a stack of multiple layers. The signal line 257 may be disposed on the second insulating structure 219 among the insulating material layers 205, 213, 214, and 219. For example, the signal line 257 may include the low potential power (VSS) line. The signal line 257 may include the first line 246-1 and the second line 255-1 on the first line 246-1.

One end of the second line 255-1 of the signal line 257 may be covered with the second planarization layer 252 extending from the display area AA. In an example, the other end of the second line 255-1 may not be covered with the dam DM so as to be exposed.

The plurality of structures BS1, BS2, and DM disposed in the first zone BZ1 may include the first barrier structure BS1, the second barrier structure BS2, and the dam DM. The first barrier structure BS1 among the plurality of structures BS1, BS2, and DM may be disposed on the bank 262. The first barrier structure BS1 may include the first layer 264-1 including the organic insulating material. The second barrier structure BS2 may be spaced apart from the first barrier structure BS1. The second barrier structure BS may include a structure in which the first layer 262-2 and the second layer 264-2 are stacked. Each of the first layer 262-2 and the second layer 264-2 of the second barrier structure BS2 may include an organic insulating material. The dam DM may be disposed to be spaced apart from the second barrier structure BS2. The dam DM may be closer to the second zone BZ2 than the second barrier structure BS2 may be.

The anode electrode part 261′ extending from the display area AA may be disposed on the second planarization layer 252. The anode electrode part 261′ may extend from the second planarization layer 252 and may be electrically connected to the signal line 257. For example, the anode electrode part 261′ may be in direct contact with the second line 255-1 of the signal line 257.

One end of the anode electrode part 261′ may be covered with the first layer 262-2 of the second barrier structure BS2. The anode electrode part 261′ may not extend toward the dam DM and may be broken due to the second barrier structure BS2. The second line 255-1 of the signal line 257 may be exposed through a space between the dam DM and the second barrier structure BS2.

The first encapsulation layer 271 and the third encapsulation layer 275 including an inorganic insulating material may be vertically stacked on each of the first barrier structure BS1, the second barrier structure BS2, and the dam DM. A side end 275E of the third encapsulation layer 275 among the first encapsulation layer 271 and the third encapsulation layer 275 may extend to the lower corner end 200BC_E. For example, the side end 275E of the third encapsulation layer 275 may vertically overlap the lower corner end 200BC_E.

The second line 255-1 of the signal line 257 exposed through the space between the dam DM and the second barrier structure BS2 may be covered with the first encapsulation layer 271 and the third encapsulation layer 275 including an inorganic insulating material.

Referring to FIGS. 1 and 5, an area between the dam DM and the second barrier structure BS2 disposed closer to the lower corner end 200BC_E of the lower corner area of the display panel 200 may include a broken area c from which the anode electrode part 261′ has been removed. Accordingly, even when the dam DM is damaged and moisture penetrates into the damaged portion, the anode electrode part 261′ is absent in the broken area c between the dam DM and the second barrier structure BS2, thereby preventing moisture from flowing to the second barrier structure BS2.

For example, when a damage point occurs in a predetermined area of the dam DM, the damage point may be a path through which moisture penetrates. As the dam DM includes an organic insulating material, moisture penetrating through the damage point may flow along the first direction as the row direction along the shape of the dam DM. For example, the first direction may be an X-axis direction, and may also be referred to as a row direction.

However, a situation in which the moisture flows along the shape of the dam DM may occur. However, a portion of the anode electrode part 261′ between the dam DM and the second barrier structure BS2 is cut off in the broken area c. Accordingly, as indicated by the arrow, the moisture may be prevented from flowing in the second direction intersecting the first direction. For example, the second direction may be an Y-axis direction, and may be referred to as the column direction in the plan view of the display device.

This may prevent the moisture from flowing in the second direction intersecting the first direction through the anode electrode part 261′ and then flowing into the display area AA. Therefore, since a signal or voltage for the operation of the display area AA may be stably provided, product reliability may be improved.

In addition, the broken area c of the anode electrode 261 may be covered with an inorganic insulating structure. For example, the inorganic insulating structure may include the first encapsulation layer 271 and the third encapsulation layer 275. However, embodiments of the present disclosure are not limited thereto. Each of the first encapsulation layer 271 and the third encapsulation layer 275 may include an inorganic insulating material layer. Accordingly, since the broken area c is covered with the inorganic insulating structure, a structure robust against moisture penetration into the broken area may be realized.

In the lower corner area of the display panel 200 including the lower corner end 200BC_E of the display panel 200, all of the first barrier structure BS1, the second barrier structure BS2, and the dam DM including an organic insulating material may be covered with the inorganic insulating material. That is, since all of the films including the organic insulating material are covered with the film including the inorganic insulating material, a structure robust against moisture penetration thereto may be realized.

In addition, since the second line 255-1 of the signal line 257 exposed through the broken area c between the dam DM and the second barrier structure BS2 is covered with the first encapsulation layer 271 and the third encapsulation layer 275 including an inorganic insulating material, the moisture may not flow through the second barrier structure BS2. Accordingly, a structure that is robust against moisture penetration may be realized.

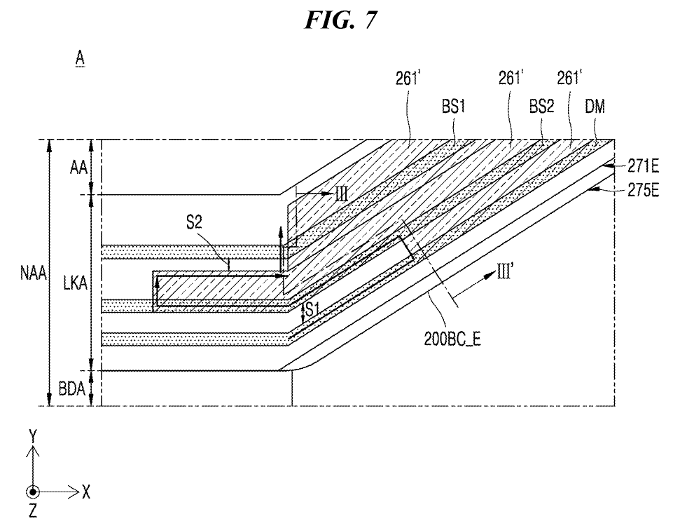

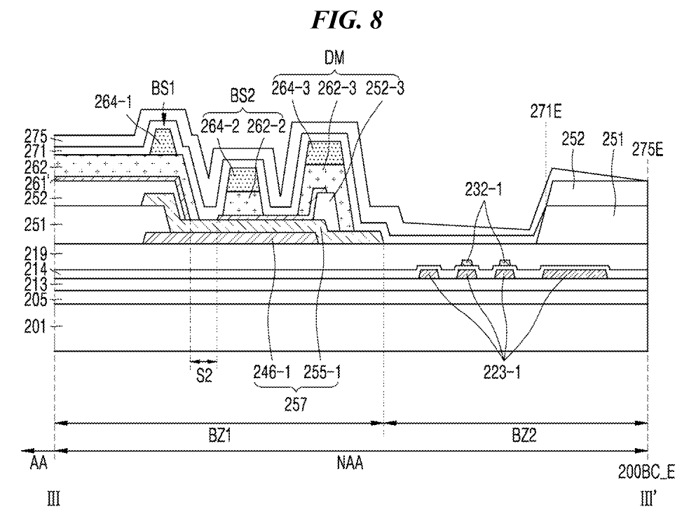

FIGS. 7 and 8 are views according to still another embodiment of the present disclosure. FIG. 7 is an enlarged plan view of the area A of FIG. 1. FIG. 8 is a cross-sectional view taken along a line III-III' of FIG. 7. In FIGS. 7 and 8, descriptions of the same components as those of FIGS. 3 and 4 will be briefly or omitted. The same constituent elements may employ the same reference numerals.

Referring to FIGS. 7 and 8, a portion of the non-display area NAA disposed in the lower corner area of the display panel 200 may include the first zone BZ1 and the second zone BZ2. The first barrier structure BS1, the second barrier structure BS2, and the dam DM may be disposed in the first zone BZ1. The second zone BZ2 may be located outwardly of the first zone BZ1.

The insulating material layers 205, 213, 214, and 219 extending from the display area AA may be sequentially stacked on the substrate 201 in the first zone BZ1. The signal line 257 may be disposed on the second insulating structure 219 among the insulating material layers 205, 213, 214, and 219. For example, the signal line 257 may include the low potential power (VSS) line. The signal line 257 may include the first line 246-1 and the second line 255-1 disposed on the first line 246-1.

The plurality of structures BS1, BS2, and DM disposed in the first zone BZ1 may include the first barrier structure BS1, the second barrier structure BS2, and the dam DM. For example, each of the plurality of structures BS1, BS2, and DM may be disposed to overlap the signal line 257 in the vertical direction.

Among the plurality of structures BS1, BS2, and DM, the first barrier structure BS1 may be disposed closest to the display area AA, and the dam DM may be disposed at a position farthest from the display area AA and may be disposed closest to the lower corner end 200BC_E. The second barrier structure BS2 may be disposed between the first barrier structure BS1 and the dam DM.

The first barrier structure BS1 may be disposed on the bank 262 and may include the first layer 264-1 including an organic insulating material. The second barrier structure BS2 may include the first layer 262-2 and the second layer 264-2 disposed on the first layer 262-2. Each of the first layer 262-2 and the second layer 264-2 of the second barrier structure BS2 may include an organic insulating material. The dam DM may be a structure in which the first layer 252-3, the second layer 262-3, and the third layer 264-3 are sequentially stacked such that the first layer 252-3 is the lowest layer. Each of the first layer 252-3, the second layer 262-3, and the third layer 264-3 of the dam DM may include an organic insulating material.

One end of the second line 255-1 of the signal line 257 may be covered with the second planarization layer 252. In an example, the other end of the second line 255-1 may not be covered with the dam DM so as to be exposed.

The anode electrode part 261′ extending from the display area AA may be disposed on the second planarization layer 252. The anode electrode part 261′ may extend from the second planarization layer 252 and may be electrically connected to the signal line 257. For example, the anode electrode part 261′ may be in direct contact with the second line 255-1 of the signal line 257.

The anode electrode part 261′ may include a plurality of broken areas S1 and S2 in which the anode electrode part 261′ is broken between the first barrier structure BS1 and the second barrier structure BS2. For example, the broken areas S1 and S2 of the anode electrode part 261′ may include a first broken area S1 disposed between the second barrier structure BS2 and the dam DM and a second broken area S2 disposed between the first barrier structure BS1 and the second barrier structure BS2. However, embodiments of the present disclosure are not limited thereto. The first broken area S1 and the second broken area S2 may be disposed at different positions so as not to overlap each other in the second direction Y as the column direction of the display panel 200.

Referring to FIG. 7, in each of the plurality of broken areas S1 and S2, the anode electrode part 261′ is broken or discontinuous in the second direction Y as the column direction of the display panel 200. As the anode electrode part 261′ is cut off in the second broken area S2 between the first barrier structure BS1 and the second barrier structure BS2, a portion of the surface of the second line 255-1 of the signal line 257 may be exposed in the second broken area S2.

In an example, the anode electrode part 261′ may include a first portion disposed on the side in the Y direction of the broken areas S1 and S2, and a second portion disposed on the other side in the Y direction of the broken areas S1 and S2 while the broken areas S1 and S2 are interposed between the first and second portions. For example, the first portion of the anode electrode part 261′ may be disposed at a position closer to the display area AA, and the second portion thereof may be disposed at a position closer to the lower corner end 200BC_E of the display panel.

For example, the second broken area S2 among the plurality of broken areas S1 and S2 is interposed between one side and the other side in the Y-direction of the first portion of the anode electrode part 261′. In this case, the one side thereof may be covered with the bank 262. An end of the second portion of the anode electrode part 261′ may be covered with the dam DM. For example, the other end of the second portion of the anode electrode part 261′ may be covered with the second layer 263-3 of the dam DM.

The first encapsulation layer 271 and the third encapsulation layer 275 including an inorganic insulating material may be vertically stacked on each of the first barrier structure BS1, the second barrier structure BS2, and the dam DM. The side end 275E of the third encapsulation layer 275 among the first encapsulation layer 271 and the third encapsulation layer 275 may extend to the lower corner end 200BC_E. For example, the side end 275E of the third encapsulation layer 275E may vertically overlap the lower corner end 200BC_E.

A portion of the second line 255-1 of the signal line 257 exposed through each of the broken areas S1 and S2 between the first barrier structure BS1 and the second barrier structure BS2 may be covered with the first encapsulation layer 271 and the third encapsulation layer 275 including an inorganic insulating material.

The anode electrode part 261′ may have at least one broken area S1 and S2 defined between the first barrier structure BS1 and the second barrier structure BS2. In the broken area, the anode electrode may be cut off or discontinuous in the second direction Y (see FIG. 7) as the column direction in the plan view of the display panel. Accordingly, a pattern length of the anode electrode part 261′ which may act as a moisture penetration path may increase in the first direction X (see FIG. 7) as the row direction of the display panel. Accordingly, in a situation in which the moisture penetrates through the moisture inflow point of the first zone BZ1 where the end of the signal line 257 is exposed, the length of the moisture penetration path increases, thereby delaying the time for which moisture penetrates into the display area AA.

For example, referring to FIG. 7, as the non-display area NAA becomes narrower as the non-display area NAA extends toward the lower side end 200B_E of the display panel, a point where the first encapsulation layer 271 and the third encapsulation layer 275 meet each other at the lower corner end 200BC_E may occur. A point at which the first encapsulation layer 271 and the third encapsulation layer 275 meet each other may include an end of the second signal line 255-1 of the signal line 257. The end of the second signal line 255-1 may not be covered with any one of the first layer 252-3, the second layer 262-3, or the third layer 264-3 of the dam DM. Accordingly, the end of the second signal line 255-1 may be covered with the first encapsulation layer 271 and the third encapsulation layer 275. However, the thickness of the portion of the first encapsulation layer 271 covering the end of the second signal line 255-1 decreases as the portion extends toward the lower corner end 200BC_E and the side 271E of the first encapsulation layer 271, so that the portion covering the end of the signal line 257 may become a moisture introduction point (or moisture ingress vulnerability point).

The moisture penetrating through the moisture inflow point may flow along the shape of the dam DM including the organic insulating material in the first direction which is the row direction of the display panel. The moisture may flow in the second direction which is the column direction of the display panel through the second portion of the anode electrode part 261′ disposed between the dam DM and the second barrier structure BS2, and then may flow along the first direction as the row direction of the display panel along the shape of the second barrier structure BS2. For example, the first direction may be an X-axis direction, and may also be referred to as the row direction. For example, the second direction may be an Y-axis direction, and may be referred to as the column direction.

In this regard, a plurality of opening holes may be defined in a portion of the anode electrode part 261′ extending from the left or right lower corner end 200BC_E to the right or left side of the display panel. As the plurality of opening holes serve to break the anode electrode part 261′, moisture may not flow from each of the left or right lower corner end 200BC_E to the right or left direction of the display panel.

In addition, as the anode electrode part 261′ is cut off in the first broken area S1 disposed between the dam DM and the second barrier structure BS2 or the second broken area S2 disposed between the second barrier structure BS2 and the first barrier structure BS1, the moisture may be prevented from flowing to the first portion of the anode electrode part 261′. Accordingly, since the length of the moisture penetration path increases, the time for moisture to penetrate into the display area AA may be delayed. Therefore, since a signal or voltage for the operation of the display area AA may be stably provided, product reliability may be improved.

In addition, all of the first barrier structure BS1, the second barrier structure BS2, and the dam DM including the organic insulating material may be covered with the inorganic insulating material in the lower corner area in the plan view of the display panel 200 including the (right and left) lower corner end 200BC_E of the display panel 200. That is, since all of the films including the organic insulating material are covered with the film including the inorganic insulating material, the structure that is robust against moisture penetration may be secured.

In addition, since the second line 255-1 of the signal line 257 exposed through the second broken area S2 defined between the first barrier structure BS1 and the second barrier structure BS2 is covered with the first encapsulation layer 271 including an inorganic insulating material and the third encapsulation layer 275, the moisture may not flow through the first barrier structure BS1. Accordingly, a structure that is robust against moisture penetration may be realized.

In an embodiment of the present disclosure, the anode electrode may be prevented from acting as a moisture penetration path or the length of the moisture penetration path may be increased to increase the time for moisture to penetrate into the display area. Accordingly, a defect rate of the display device due to moisture penetration into the display area may be reduced. Therefore, the production energy required for additional production of the display device may be reduced, such that the greenhouse gas emission may be reduced.

A display device according to one aspect and various embodiments of the present disclosure may be described as follows.

One aspect of the present disclosure provides a display device comprising a substrate including.

In accordance with some embodiments, an end of the anode electrode is covered with at least one of the plurality of structures.

In accordance with some embodiments, the display device further comprises a signal line disposed on the non-display area and electrically connected to the anode electrode.

In accordance with some embodiments, the signal line includes a low potential power line.

In accordance with some embodiments, the non-display area includes: a first zone adjacent to the display area; and a second zone positioned outwardly of and surrounding the first zone.

In accordance with some embodiments, each of the plurality of structures includes an organic insulating material.

In accordance with some embodiments, the plurality of structures include: a first barrier structure disposed in the first zone, wherein the first barrier structure among the plurality of structures is closest to the display area; a dam disposed in the first zone, wherein the dam among the plurality of structures is closest to the lower corner end; and a second barrier structure disposed between the first barrier structure and the dam.

In accordance with some embodiments, the broken area of the anode electrode is positioned between the second barrier structure and the dam.

In accordance with some embodiments, one side end of the anode electrode is covered with the second barrier structure.

In accordance with some embodiments, the broken area of the anode electrode is disposed between the first barrier structure and the second barrier structure.

In accordance with some embodiments, the anode electrode includes a first portion disposed on one side of the broken area and a second portion disposed on the other side of the broken area, wherein at least one end of the second portion of the anode electrode is covered with the dam.

In accordance with some embodiments, the display device further comprises an inorganic insulating structure covering the plurality of structures, wherein the broken area of the anode electrode is covered with the inorganic insulating structure.

In accordance with some embodiments, the at least one broken area of the anode electrode includes: a first broken area disposed between the second barrier structure and the dam; and a second broken area between the first barrier structure and the second barrier structure.

In accordance with some embodiments, the first broken area and the second broken area are disposed at different positions.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a substrate including a display area and a non-display area surrounding the display area in a plan view of the display device;
a bendable area disposed in the non-display area;
a lower corner area disposed in the non-display area and connected to the bendable area, wherein the lower corner area has a lower corner end;
a plurality of structures disposed on the substrate and in the lower corner area and spaced apart from each other in the plan view; and
an anode electrode disposed on the substrate and in the non-display area,
wherein the anode electrode has at least one broken area disposed between adjacent ones of the plurality of structures in the plan view.

2. The display device of claim 1, wherein an end of the anode electrode is covered with at least one of the plurality of structures.

3. The display device of claim 1, wherein the display device further comprises a signal line disposed on the non-display area and electrically connected to the anode electrode.

4. The display device of claim 3, wherein the signal line includes a low potential power line.

5. The display device of claim 1, wherein the non-display area includes:
a first zone adjacent to the display area; and
a second zone positioned outwardly of and surrounding the first zone.

6. The display device of claim 1, wherein each of the plurality of structures includes an organic insulating material.

7. The display device of claim 5, wherein the plurality of structures include:
a first barrier structure disposed in the first zone, wherein the first barrier structure among the plurality of structures is closest to the display area;
a dam disposed in the first zone, wherein the dam among the plurality of structures is closest to the lower corner end; and
a second barrier structure disposed between the first barrier structure and the dam.

8. The display device of claim 7, wherein the broken area of the anode electrode is positioned between the second barrier structure and the dam.

9. The display device of claim 8, wherein one side end of the anode electrode is covered with the second barrier structure.

10. The display device of claim 7, wherein the broken area of the anode electrode is disposed between the first barrier structure and the second barrier structure.

11. The display device of claim 10, wherein the anode electrode includes a first portion disposed on one side of the broken area and a second portion disposed on the other side of the broken area,
wherein at least one end of the second portion of the anode electrode is covered with the dam.

12. The display device of claim 1, wherein the display device further comprises an inorganic insulating structure covering the plurality of structures,
wherein the broken area of the anode electrode is covered with the inorganic insulating structure.

13. The display device of claim 7, wherein the at least one broken area of the anode electrode includes:
a first broken area disposed between the second barrier structure and the dam; and
a second broken area between the first barrier structure and the second barrier structure.

14. The display device of claim 13, wherein the first broken area and the second broken area are disposed at different positions.
